(19) United States
(12) Patent Application Publication
(10) Pub. No.: US 2017/0287727 A1
(43) Pub. Date: Oct. 5, 2017

(54) METAL HARD MASK AND METHOD OF MANUFACTURING SAME

(71) Applicant: TOKYO ELECTRON LIMITED, Tokyo (JP)

(72) Inventors: Yuuki KIKUCHI, Yamanashi (JP); Hiroyuki NAGAI, Yamanashi (JP); Yoshihiro HIROTA, Yamanashi (JP); Mikio SUZUKI, Yamanashi (JP)

(21) Appl. No.: 15/513,718

(22) PCT Filed: Jul. 10, 2015
(86) PCT No.: PCT/JP2015/069900

§ 371 Date: Mar. 23, 2017

(30) Foreign Application Priority Data
Sep. 25, 2014 (JP) 2014-194963

(51) Int. Cl. H01L 21/311; C23C 14/14; H01L 21/768

(52) U.S. Cl. CPC H01L 21/31144; H01L 21/768; C23C 14/14; H01L 21/311

(57) ABSTRACT

A metal hard mask for etching an etching target film that is present on a target object to be processed is formed of an amorphous alloy film that is formed by a thin film formation technique. It is preferable to use a physical vapor deposition method as the thin film formation technique, and sputtering is suitable for the use among physical vapor deposition methods. This metal hard mask is obtained by forming an amorphous alloy film on the etching target film by a thin film formation technique and patterning the amorphous alloy film.

### CROSS REFERENCE TO RELATED APPLICATIONS

This application is a National Stage Application of, and claims priority to, PCT Application No. PCT/JP2015/069900, filed on Jul. 10, 2015, entitled “METAL HARD MASK AND METHOD OF MANUFACTURING SAME,” which claims priority to Japanese Patent Application No. 2014-194963, filed on Sep. 25, 2014. The foregoing patent applications are herein incorporated by reference by entirty for all purposes.

### FIELD OF THE INVENTION

The present invention relates to a metal hard mask for use in an etching of an interlayer dielectric film or the like and a method of manufacturing same.

### BACKGROUND OF THE INVENTION

In a semiconductor device manufacturing process, there is a step of processing a film to have, e.g., a trench or a hole by a plasma etching, and a resist mask has been conventionally used as a mask in the etching. However, with the miniaturization of the pattern, a material of the resist mask has a low resistance against an etching gas or a plasma, which makes it difficult to maintain the pattern until the end of the etching. Therefore, a metal hard mask is used which is formed by transferring the pattern of the resist mask to a metal hard mask layer by an etching.

For an etching of an interlayer dielectric film during a formation of a wiring pattern, a hard TiN film having a high etching resistance has been used as the metal hard mask (e.g., Patent Document 1).

Patent Document 1: Japanese Patent Application Publication No. 2013-98193

However, since the TiN film has a high film stress, it causes a distortion (wiggling) of the wiring after the etching of the interlayer dielectric film in the formation of the wiring pattern. Such wiggling of the wiring becomes significant as the wiring becomes fine in response to a device scaling (miniaturization) or when a porous Low-k film having a low dielectric constant and a low strength is used as the interlayer dielectric film in order to achieve a high-speed semiconductor device. Therefore, there is a strong demand for a metal hard mask having a low film stress.

### SUMMARY OF THE INVENTION

In view of the above, the present invention provides a metal hard mask having a low film stress and a method of manufacturing the same.

In accordance with an aspect of the present invention, there is provided a metal hard mask for etching an etching target film formed on a target object to be processed, the metal hard mask including: an amorphous alloy film formed by a thin film forming method.

In accordance with another aspect of the present invention, there is provided a method of manufacturing a metal hard mask for etching an etching target film formed on a target object to be processed, the method including: forming an amorphous alloy film on the etching target film by a thin film forming method, and obtaining the metal hard mask by patterning the amorphous alloy film.

Further, the thin film forming method may be a physical vapor deposition method, a sputtering may be used as the physical vapor deposition method.

The amorphous alloy film may be made of two kinds of metal elements and, in a combination of the metal elements, the crystal structures obtained by the respective metal elements are different from each other. Further, the amorphous alloy film may be made of an alloy selected from the group consisting of Al—Si, Si—Ti, Nb—Ni, Ta—Zr, Ti—W, and Zr—W.

Further, the etching target film may be an interlayer dielectric film, and the interlayer dielectric film serving as the etching target film is a porous Low-k film.

In accordance with the present invention, since the amorphous alloy film, which is formed by the thin film forming method, is used as the metal hard mask, it is possible to significantly reduce the film stress compared to a case of using a crystalline film such as the TiN film.

Therefore, it becomes possible to reduce the wiggling of the wiring even when a film having the low strength such as the porous Low-k film is used as the etching target film.

### BRIEF DESCRIPTION OF THE DRAWINGS

FIGS. 1A and 1B are cross-sectional views showing an application example of a metal hard mask in accordance with an embodiment of the present invention.

FIG. 2 is a plan view showing a wiggling of a wiring when a TiN film is used as the metal hard mask and a porous Low-k film is used as an interlayer dielectric film serving as an etching target film.

FIG. 3 is a cross-sectional view showing a schematic configuration of a magnetron sputtering apparatus, which is an example of a film forming apparatus for forming an amorphous alloy film constituting the metal hard mask.

FIG. 4A is a plan view showing a LER in the case of using the TiN film as the metal hard mask.

FIG. 4B is a plan view showing a LER in the case of using the amorphous alloy film as the metal hard mask.

FIG. 5 is a diagram showing a structure of a sample used in an experimental example.

FIG. 6A shows a XRD spectrum obtained by an out-of-plane measurement when PVD-Al₂₀Si₈₀ is used as an evaluation metal film.

FIG. 6B shows a XRD spectrum obtained by an in-plane measurement in the case of using PVD-Al₂₀Si₈₀ as the evaluation metal film. FIG. 7A shows a XRD spectrum obtained by the out-of-plane measurement when PVD-Si₁₅Ti₈₅ is used as the evaluation metal film.

FIG. 7B shows a XRD spectrum obtained by the in-plane measurement in the case of using PVD-Si₁₅Ti₈₅ as the evaluation metal film.

FIG. 8A shows a XRD spectrum obtained by the out-of-plane measurement when PVD-Nb₄₅Ni₅₅ is used as the evaluation metal film.

FIG. 8B shows a XRD spectrum obtained by the in-plane measurement in the case of using PVD-Nb₄₅Ni₅₅ as the evaluation metal film.

FIG. 9A shows a XRD spectrum obtained by the out-of-plane measurement when PVD-Ta₅₀Zr₅₀ is used as the evaluation metal film.

FIG. 9B shows a XRD spectrum obtained by the in-plane measurement in the case of using PVD-Ta₅₀Zr₅₀ as the evaluation metal film.

FIG. 10 is a view illustrating a measurement result of a film stress of each evaluation metal film in the experimental example.

FIGS. 11A and 11B are views illustrating an etching result of an evaluation alloy film of each sample in the experimental example.

### DETAILED DESCRIPTION OF THE EMBODIMENTS

Hereinafter, various embodiments will be described in detail with reference to the accompanying drawings.

### Application Example of Metal Hard Mask

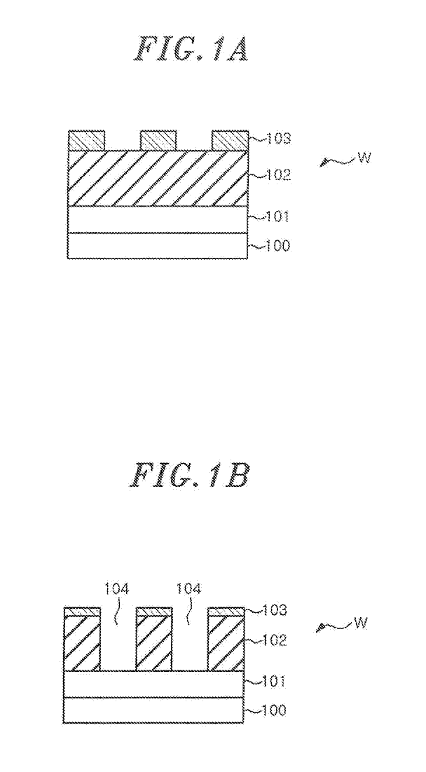

FIGS. 1A and 1B are cross-sectional views showing an application example of a metal hard mask in accordance with an embodiment of the present invention.

Here, the metal hard mask according to the present embodiment is used as a mask for plasma-etching an interlayer dielectric film. In the present embodiment, as shown in FIG. 1A, there is provided a semiconductor wafer W in which an interlayer dielectric film 102 is formed on a lower structure 101 (details omitted) formed on a Si substrate 100 serving as a target object to be processed, and a metal hard mask 103 according to the present embodiment is formed on the interlayer dielectric film 102 in a predetermined pattern. Then, as shown in FIG. 1B, the interlayer dielectric film 102 is plasma-etched by using the metal hard mask 103 as a mask to form trenches 104 as recesses of a predetermined pattern in the interlayer dielectric film 102.

In the case of employing a dual-damascene process, via holes are formed at bottom portions of the trenches 104. However, the trenches 104 may be formed after forming the via holes (not shown) by using a predetermined mask, or the via holes may be formed after forming the trenches 104 by using a predetermined mask.

Further, a buffer film may be formed between the interlayer dielectric film 102 and the metal hard mask 103 to prevent an unwanted etching of the interlayer dielectric film 102 due to an elimination of the metal hard mask 103 by an etching of the metal hard mask 103.

### Alloy Film Constituting Metal Hard Mask

The metal hard mask 103 is made of an amorphous alloy film which is patterned. Specifically, a film is formed by a thin film forming method and then the film is patterned by an appropriate method to form the metal hard mask 103. As an example of the patterning method, a plasma etching using a photolithographically-patterned photoresist as a mask may be employed.

In the present embodiment, the amorphous alloy film is an alloy film which is made of two or more kinds of metal elements and does not have clear crystallinity. The amorphous alloy film in the present embodiment may further include an alloy film partially having a microcrystalline structure. Specifically, in the present embodiment, when a film is formed to have a film thickness of 100 nm or more and its 2θ X-ray diffraction (XRD) spectrum is compared with, e.g., a database of Joint Committee on Power Diffraction Standard (JCPDS), it is the amorphous alloy film defined in this embodiment in the following cases: where diffraction peaks of constituent elements and diffraction peaks which can identify crystallized alloys or intermetallic compounds are not present; and where, even if such diffraction peaks are present, the number of the peaks is small or there are broad peaks (generally referred to as ‘halo peaks’ which characteristically appear in a spectrum of an amorphous film) which cannot belong to elements obtained in a range of a diffraction angle 2θ of 30° to 50°.

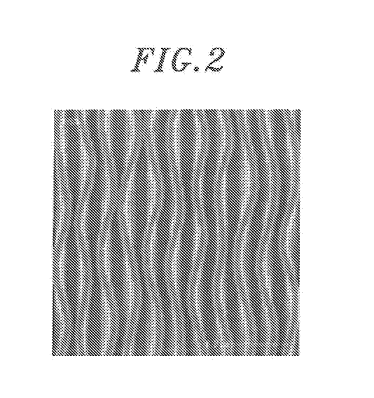

Conventionally, a TiN film is often used as a metal hard mask. However, since the TiN film has a high film stress, a wiggling of a wiring occurs after an etching of an interlayer dielectric film during a formation of a wiring pattern. As shown in FIG. 2, particularly, the wiggling of the wiring becomes significant as the wiring becomes fine in response to a device scaling (miniaturization) or when a porous Low-k film having a low dielectric constant and a low strength is used as the interlayer dielectric film in order to achieve a high-speed semiconductor device.

The film stress of such TiN film is generated because the TiN film has clear crystallinity. In other words, the TiN film has a polycrystal structure including a plurality of crystals grown to some extent and, thus, the film stress is generated at the grain boundaries of the crystals. It has been found that this film stress becomes more remarkable as the crystal is larger. In view of the above, in order to reduce the film stress, it has been found to be effective when the size of the crystal grain is reduced, and eventually when the crystal grain boundaries are eliminated. Therefore, in the present embodiment, an amorphous alloy film where basically no crystal grain boundary exists is used as the metal hard mask. This makes it possible to significantly reduce the film stress due to crystals of the metal hard mask.

Further, in order to transfer a mask pattern onto an underlying film, an etching selectivity is required between the metal hard mask and an etching target film such that the metal hard mask is hardly etched compared to the underlying film. By employing the amorphous alloy film of the present embodiment, it is possible to obtain the metal hard mask, which is difficult to be etched in a general plasma etching as compared to the TiN film. Further, it is also possible to sufficiently increase the etching selectivity of the interlayer dielectric film such as the Low-k film serving as the etching target film.

As for the amorphous alloy film used for the metal hard mask of the present embodiment, it is preferable to use an alloy film made of two kinds of metal elements of element A and element B and, in this combination, it is preferable that the crystal structures obtained by the respective metal elements are different from each other. As a result, it is considered that the amorphous structure easily occurs due to the mismatch of the lattice constants and the like.

A crystal structure of a single metal is mainly classified into a cubic system, a hexagonal system, and a tetragonal system. As examples of basic unit lattices, a body-centered cubic (bcc) lattice and a face-centered cubic (fcc) lattice of the cubic system and a hexagonal close-packed (hcp) lattice of the hexagonal system may be mentioned. As examples of metals having the bcc crystal structure, α-Fe, W, Mo, Nb, Cr and the like may be mentioned. Further, as examples of metals having the fcc crystal structure, Au, Ag, Cu, Ni, Al and the like may be mentioned. Further, as examples of metals having the hcp crystal structure, Zr, Mg, Ti and the like may be mentioned. As metals other than the metals having the aforementioned structures, Si and Ta may be mentioned. Although the crystal structure of Si belongs to the cubic system, it is a structure (diamond structure) other than the bcc structure and the fcc structure. In addition, Ta has a bcc & tetragonal structure.

Among these metal elements, an alloy combination, which has different crystal structures to allow the amorphous alloy film to be easily obtained and is also highly suitable for the metal hard mask, can be exemplified as follows:

Al—Si (combination of fcc and other cubic);

Si—Ti (combination of other cubic and hcp);

Nb—Ni (combination of bcc and fcc);

Ta—Zr (combination of bcc & tetragonal and hcp);

Ti—W (combination of hcp and bcc); and

Zr—W (combination of hcp and bcc).

Further, in the case of Cr—W which is a combination of metal elements having the same bcc structure, it is unable to produce an amorphous alloy.

In addition, as another indicator for manufacturing the amorphous alloy film, the amorphous alloy film can be manufactured when a difference in the atomic radius between elements A and B is 12% or more as a condition for manufacturing an amorphous alloy in a conventional quenching method, or when elements are combined in an alloy such that the free energy of the alloy is lower than that of each of the elements A and B as a condition for manufacturing an amorphous alloy in a conventional quenching method.

The composition ratio of the alloy for obtaining the amorphous alloy is not particularly limited. However, in consideration of the description of published documents or the binary phase diagram for each alloy, Si may be in a range from 10 at. % to 90 at. % in the Al—Si alloy; Ti may be in a range from 80 at. % to 95 at. % in the Si—Ti alloy; Ni may be in a range from 51 at. % to 68 at. % in the Nb—Ni alloy; Zr may be in a range from 36 at. % to 53 at. % in the Ta—Zr alloy; W may be in a range from 28 at. % to 78 at. % in the Ti—W alloy; and W may be in a range from 23 at. % to 78 at. % in the Zr—W alloy.

### Film Forming Method

In order to form the amorphous alloy film constituting the metal hard mask 103, the thin film forming method is used. However, the amorphous alloy film is easily crystallized when heated during the film formation and, thus, it is preferable to use a film forming method with no heating process. In this connection, a physical vapor deposition (PVD) method can be preferably used and, more particularly, a sputtering such as a magnetron sputtering can be suitably used among various examples of the PVD method such as the sputtering, a vacuum deposition, an ion plating and the like.

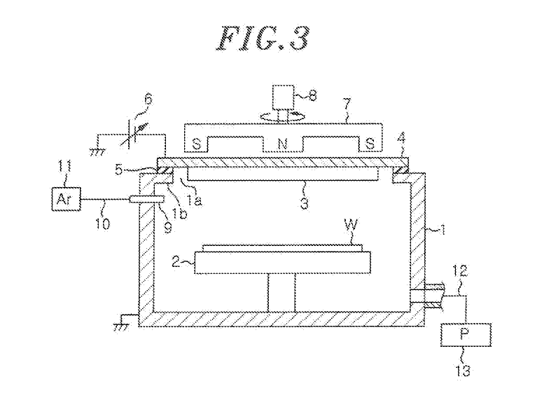

FIG. 3 shows a schematic configuration of a magnetron sputtering apparatus. The magnetron sputtering apparatus includes a processing chamber 1, and a mounting table 2 for mounting thereon a semiconductor wafer W serving as a target object to be processed is provided in the processing chamber 1. An opening 1a is formed at an upper portion of the processing chamber 1, and an annular lid 1b is formed at an upper end of the processing chamber 1. A conductive target holding member 4 is provided on the lid 1b to cover the opening 1a through an insulating member 5 disposed therebetween. A target 3 having the composition of a desire amorphous alloy film is held on a bottom surface of the target holding member 4. A DC power source 6 is connected to the target holding member 4, so that a negative DC voltage is applied to the target 3 from the DC power source through the target holding member 4. A magnet 7 is disposed above the target holding member 4 to rotate horizontally by means of a motor 8. At an upper portion of a side wall of the processing chamber 1, a gas inlet nozzle 9 is inserted into the processing chamber 1, and the gas inlet nozzle 9 is connected to an Ar gas supply source 11 through a gas supply line 10. Ar gas is supplied into the processing chamber 1 from the Ar gas supply source 11 through the gas supply line 10 and the gas inlet nozzle 9. Further, an exhaust line 12 is connected to a lower portion of the side wall of the processing chamber 1, and the processing chamber 1 is vacuum-evacuated through the exhaust line 12 by a vacuum pump 13.

In this magnetron sputtering apparatus, the Ar gas is supplied into the processing chamber 1 from the Ar gas supply source 11 in a state where the semiconductor wafer W is mounted on the mounting table 2 while exhausting the inside of the processing chamber 1 by the vacuum pump 13, thereby maintaining the inside of the processing chamber 1 under a predetermined vacuum atmosphere. In this state, the negative DC voltage is applied from the DC power source 6 to the target 3 while a horizontal magnetic field is formed by rotating the magnet 7. When the negative DC voltage is applied to the target 3, the Ar gas is ionized by an electric field thus formed to thereby generate electrons. These electrons are drifted by the horizontal magnetic field and the electric field and, thus, a high-density plasma is formed. Then, Ar ions in the plasma sputter the target 3, so that metal particles are sputtered, and the sputtered metal particles are deposited on an etching target film (underlying film) of the semiconductor wafer W to form the alloy film.

In order for the alloy film thus formed to be the amorphous alloy film, it is preferable that the wafer W is maintained at a room temperature (about 25° C.) and a film forming pressure (pressure in the processing chamber) is maintained to 2 Pa or below, e.g., 0.54 Pa. Since the grain boundaries are generated in the film when the film forming pressure is 2.5 Pa or more, the pressure is a key factor for reliably forming the amorphous alloy film. The negative DC power for generating the discharge is preferably in a range from 15 W to 180 W, e.g., 30 W in absolute value.

### Effects of Embodiment

As described above, the amorphous alloy film, which is formed by the thin film forming method, more preferably, by the PVD method, is used as the metal hard mask in the present embodiment. Therefore, it is possible to significantly reduce the film stress compared to the case of using a crystalline film such as the TiN film. Specifically, an absolute value of the film stress lies in a range from about 300 MPa to about 3 GPa in the TiN film. However, this can be reduced to 100 MPa or less in the present embodiment. Therefore, it is possible to reduce a wiggling of the wiring even when a low strength film such as a porous Low-k film is used as the etching target film.

The amorphous alloy film of the present embodiment is difficult to be etched in a general plasma etching condition as compared with the TiN film, which sufficiently increases the etching selectivity of the interlayer dielectric film serving as the etching target film. Further, the amorphous alloy film can be formed to be thinner than the TiN film and has better transferability as the metal hard mask than the TiN film.

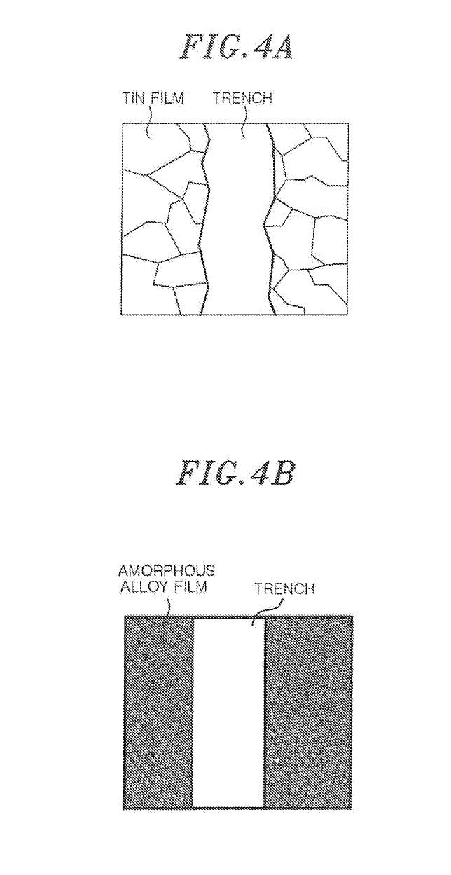

Further, when the TiN film having crystal grain boundaries is used as the metal hard mask, a line edge roughness (LER) of the wiring (trench) increases since the etching is performed along the grain boundaries as shown in FIG. 4A. However, when the amorphous alloy film is used as the metal hard mask, it is possible to reduce the LER since there is no grain boundary as shown in FIG. 4B.

### Experimental Example

Next, an experimental example will be described in detail.

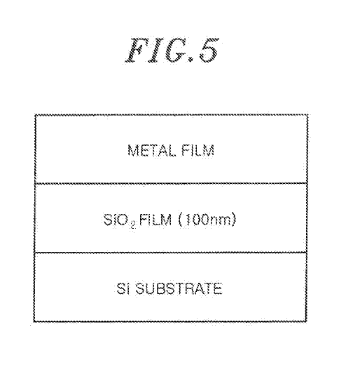

The experimental example was conducted using a sample in which, as shown in FIG. 5, a SiO₂ film having a thickness of 100 nm was formed on a Si substrate, and an evaluation metal film was formed on the SiO₂ film to have a predetermined thickness. As examples of the evaluation metal film, the following five different types of metal films were used: PVD-Al₂₀Si₈₀, PVD-Si₁₅Ti₈₅, PVD-Ta₅₀Zr₅₀, PVD-Nb₄₅Ni₅₅ and PVD-TiN.

A film formation of each evaluation metal film was carried out by using the magnetron sputtering apparatus under the following condition:

film forming pressure: 0.54 Pa

substrate temperature: room temperature of 25° C.

discharge condition: DC30W

Ar gas flow rate: 16 sccm.

(XRD)

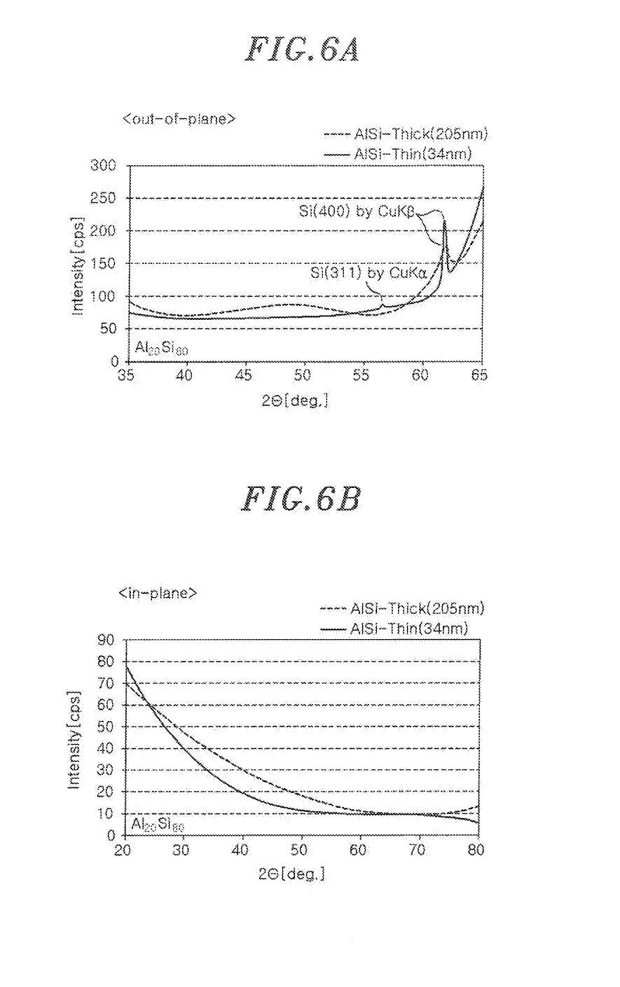

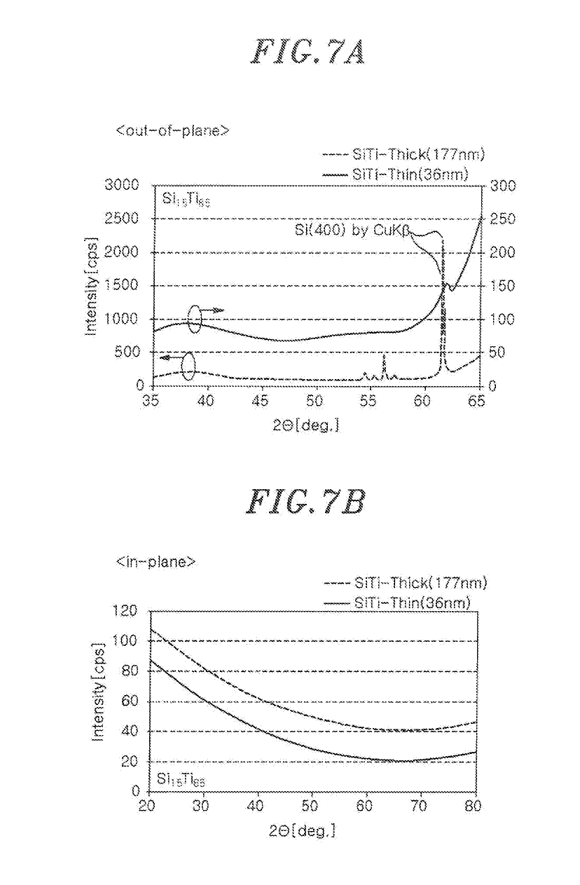

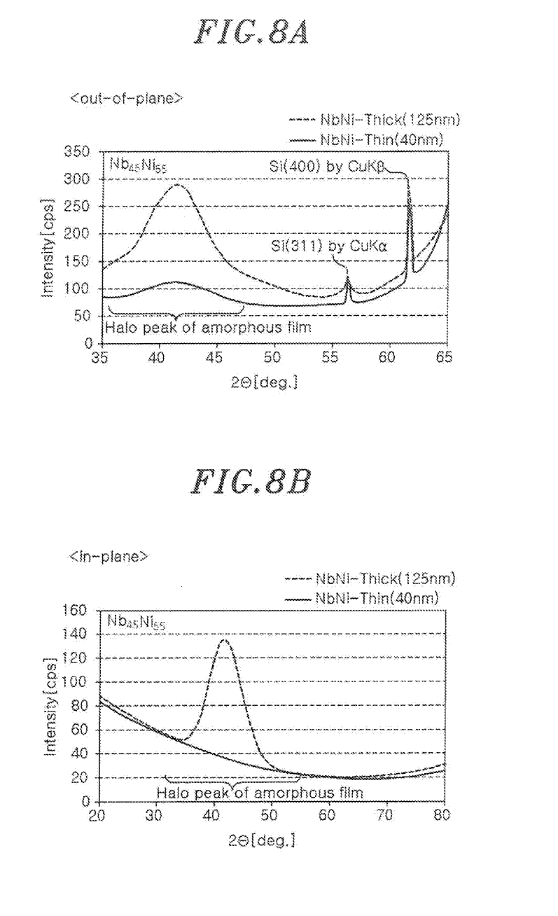

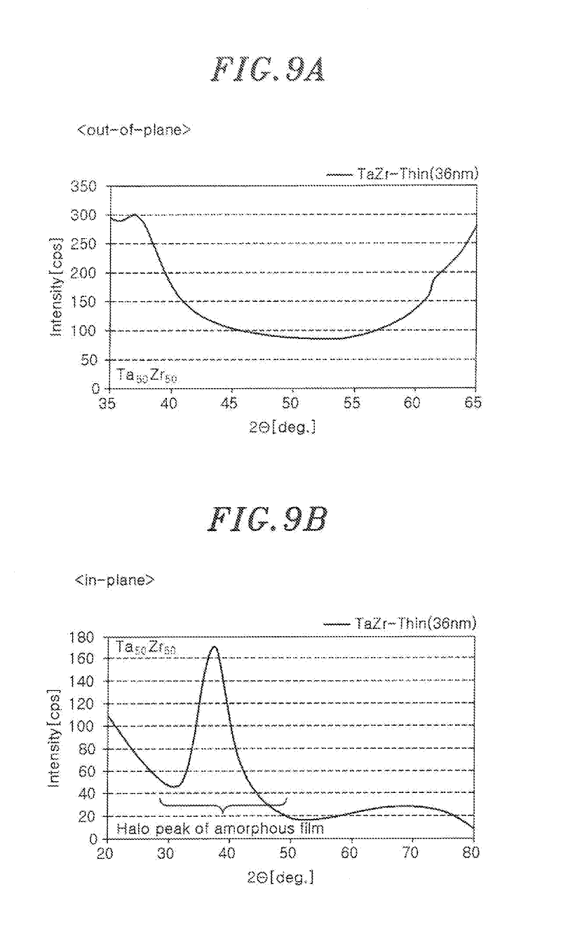

First, the crystallinity was examined by X-ray diffraction (XRD) with respect to each of PVD-Al₂₀Si₈₀, PVD-Si₁₅Ti₈₅, PVD-Ta₅₀Zr₅₀ and PVD-Nb₄₅Ni₅₅ among the evaluation metal films. Here, out-of-plane measurement and in-plane measurement were performed by CuKα ray. The XRD spectrums obtained by the out-of-plane measurement for the evaluation metal films are shown in FIG. 6A, FIG. 7A, FIG. 8A and FIG. 9A, respectively. The XRD spectrums obtained by the in-plane measurement for the evaluation metal films are shown in FIG. 6B, FIG. 7B, FIG. 8B and FIG. 9B, respectively.

Regarding PVD-Al₂₀Si₈₀, the measurement was carried out for films having thicknesses of 34 nm and 205 nm. As shown in FIGS. 6A and 6B, peaks caused by Si were observed in both films, but other peaks were not observed. Thus, it was confirmed that an amorphous alloy film was obtained.

Regarding PVD-Si₁₅Ti₈₅, the measurement was carried out for films having thicknesses of 36 nm and 177 nm. As shown in FIGS. 7A and 7B, peaks caused by Si were observed in both films, but other peaks were not observed in the film having the thickness of 36 nm. In the case of the film having the thickness of 177 nm, although few peaks indicating the presence of crystals and some peaks indicating the microcrystalline structure were observed, it can be seen that the film is almost entirely amorphous.

Regarding PVD-Nb₄₅Ni₅₅, the measurement was carried out for films having thicknesses of 40 nm and 125 nm. As shown in FIGS. 8A and 8B, peaks caused by Si were observed in both films, and other peaks in both films were only halo peaks indicating the amorphous structure, so that it was verified that an amorphous alloy film was obtained.

Regarding PVD-Ta₅₀Zr₅₀, the measurement was carried out for a film having a thickness of 36 nm. As shown in FIGS. 9A and 9B, a halo peak indicating the amorphous structure was only found, so that it was verified that an amorphous alloy film was obtained.

(Film Stress)

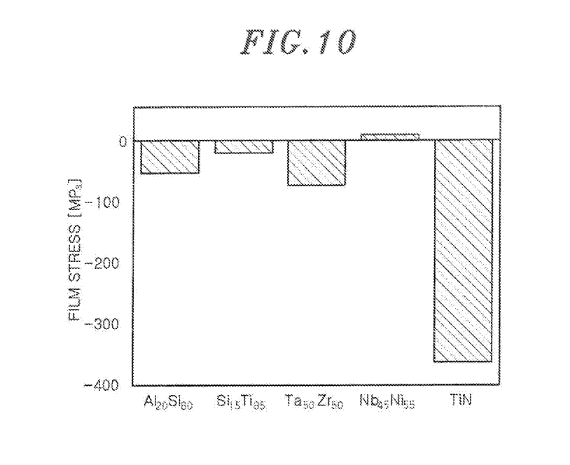

Next, the film stress of each of the evaluation metal films was measured. The result is shown in FIG. 10. In FIG. 10, the vertical axis represents a film stress, a value in a positive direction represents a compressive stress, a value in a negative direction represents a tensile stress, and an absolute value (a distance from zero) is a magnitude of the film stress. Further, the value of each evaluation metal film in FIG. 10 is an average value of two samples.

As shown in FIG. 10, the film stresses of the evaluation metal films of PVD-Al₂₀Si₈₀, PVD-Si₁₅Ti₈₅, PVD-Ta₅₀Zr₅₀ and PVD-Nb₄₅Ni₅₅ were respectively −55 MPa, −22 MPa, −75 MPa and 4 MPa while the film stress of PVD-TiN was −350 MPa. This shows that the film stresses of PVD-Al₂₀Si₈₀, PVD-Si₁₅Ti₈₅, PVD-Ta₅₀Zr₅₀ and PVD-Nb₄₅Ni₅₅, which are amorphous alloy films, are lower than that of the PVD-TiN, which is conventionally used as a metal hard mask. Therefore, it is expected that the wiggling of the wiring is difficult to occur by using each of those amorphous alloy films as the metal hard mask.

(Etching Property)

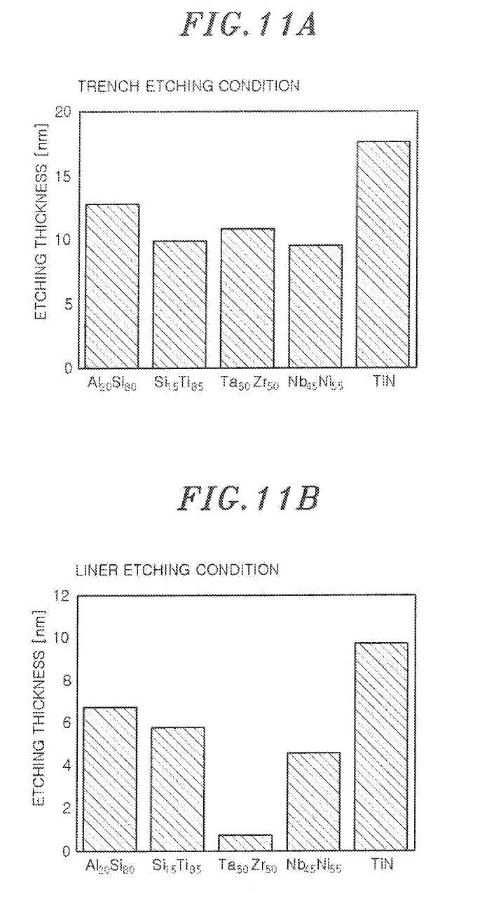

Next, for each sample, the evaluation alloy film was etched by using a parallel plate type plasma etching apparatus. The etching was performed under the general trench etching condition (pressure: 30 Pa, high frequency power: 400 W for HF only, DC voltage: 50 V, etching gases: C₄F₈, Ar, N₂ and O₂, etching time: 60 sec) and the general liner etching condition (pressure: 30 Pa, high frequency powers: HF 100 W and LF 50 W, DC voltage: 50 V, etching gases: C₄F₈, Ar, N₂ and O₂, etching time: 60 sec). The results are shown in FIGS. 11A and 11B. FIG. 11A is the result under the trench etching condition, and FIG. 11B is the result under the liner etching condition. As shown in FIGS. 11A and 11B, it was found that the amorphous alloy films of PVD-Al₂₀Si₈₀, PVD-Si₁₅Ti₈₅, PVD-Ta₅₀Zr₅₀ and PVD-Nb₄₅Ni₅₅ were difficult to be etched under any of the etching conditions as compared with the PVD-TiN. Therefore, it was verified that when the amorphous alloy film was used as the metal hard mask, it is possible to increase the etching selectivity of the underlying film (etching target film) compared to the TiN film.

### Other Applications

The present invention can be variously modified without being limited to the above embodiments. For example, in the above embodiment, the metal hard mask for etching the interlayer dielectric film has been described as an example.

However, the present invention is not limited thereto.

### EXPLANATION OF REFERENCE SYMBOLS

1: processing chamber

2: mounting table

3: target

6: DC power source

7: magnet

9: gas inlet nozzle

10: gas supply line

11: Ar gas supply source

12: exhaust line

13: vacuum pump

102: interlayer dielectric film

103: metal hard mask

104: trench

W: semiconductor wafer

What is claimed is:

1. A metal hard mask for etching an etching target film formed on a target object to be processed, the metal hard mask comprising:
an amorphous alloy film formed by a thin film forming method.

2. The metal hard mask of claim 1, wherein the thin film forming method is a physical vapor deposition method.

3. The metal hard mask of claim 2, wherein a sputtering is used as the physical vapor deposition method.

4. The metal hard mask of claim 1, wherein the amorphous alloy film is made of two kinds of metal elements and, in a combination of the metal elements, crystal structures obtained by the respective metal elements are different from each other.

5. The metal hard mask of claim 4, wherein the amorphous alloy film is made of an alloy selected from the group consisting of Al—Si, Si—Ti, Nb—Ni, Ta—Zr, Ti—W, and Zr—W.

6. The metal hard mask of claim 1, wherein the etching target film is an interlayer dielectric film.

7. The metal hard mask of claim 6, wherein the interlayer dielectric film serving as the etching target film is a porous Low-k film.

8. A method of manufacturing a metal hard mask for etching an etching target film formed on a target object to be processed, the method comprising:
forming an amorphous alloy film on the etching target film by a thin film forming method, and
obtaining the metal hard mask by patterning the amorphous alloy film.

9. The method of claim 8, wherein the thin film forming method is a physical vapor deposition method.

10. The method of claim 9, wherein a sputtering is used as the physical vapor deposition method.

11. The method of claim 8, wherein the amorphous alloy film is made of two kinds of metal elements and, in a combination of the metal elements, crystal structures obtained by the respective metal elements are different from each other.

12. The method of claim 11, wherein the amorphous alloy film is made of an alloy selected from the group consisting of Al—Si, Si—Ti, Nb—Ni, Ta—Zr, Ti—W, and Zr—W.

13. The method of claim 8, wherein the etching target film is an interlayer dielectric film.

14. The method of claim 13, wherein the interlayer dielectric film serving as the etching target film is a porous Low-k film.
